(19) United States
(12) Patent Application Publication
(10) Pub. No.: US 2017/0372910 A1
(43) Pub. Date: Dec. 28, 2017

(54) REINFORCING STRUCTURE, VACUUM CHAMBER AND PLASMA PROCESSING APPARATUS

(71) Applicant: TOKYO ELECTRON LIMITED, Tokyo (JP)

(72) Inventors: Takayuki TANAKA, Yamanashi (JP); Toshihiro KASAHARA, Yamanashi (JP); Youhei YAMADA, Yamanashi (JP)

(21) Appl. No.: 15/630,612

(22) Filed: Jun. 22, 2017

(30) Foreign Application Priority Data
Jun. 22, 2016 (JP) 2016-123367

(51) Int. Cl. H01L 21/3065; C23C 16/455; H01J 37/32

(52) U.S. Cl. CPC H01L 21/3065; H01J 37/32522; C23C 16/45563; H01J 37/321; H01J 37/32477

(57) ABSTRACT

There is provided a reinforcing structure in which a plurality of beam members provided on a top surface of a cover of a vacuum chamber for performing predetermined processing on a substrate is combined to reinforce the cover. The reinforcing structure includes a ring-shaped portion formed by arranging beam members in a ring shape at a central region of the top surface of the cover, and a radial portion formed by radially extending beam members from the ring-shaped portion.

### CROSS-REFERENCE TO RELATED APPLICATIONS

This application claims priority to Japanese Patent Application No. 2016-123367 filed on Jun. 22, 2016, the entire contents of which is incorporated herein by reference.

### FIELD OF THE INVENTION

The disclosure relates to a reinforcing structure for reinforcing a cover of a vacuum chamber, the vacuum chamber having the reinforcing structure, and a plasma processing apparatus.

### BACKGROUND OF THE INVENTION

In manufacturing a flat panel display (FPD) represented by a liquid crystal display (LCD), plasma processing such as plasma etching, sputtering, plasma CVD or the like is performed on a glass substrate for use in FPD.

In a plasma processing apparatus for performing the plasma processing, vacuum processing is required and, thus, a vacuum chamber, which can be evacuated, is used as a processing chamber. The vacuum chamber includes a main body and a cover having thicknesses enough to endure a pressure difference between the inside and the outside of the vacuum chamber.

Recently, however, a FPD substrate is considerably scaled up and a large FPD substrate has a side length of more than 2 meters. A large vacuum chamber corresponding to the large FPD substrate requires an extremely large thickness in order to ensure strength against an atmospheric pressure. As a result, a weight is increased and a material cost or a manufacturing cost is considerably increased.

As a technique for solving the above drawbacks, in Japanese Patent No. 5285403, a reinforcing structure including beam members is provided at an outer side of an upper part (cover) of a vacuum chamber. Accordingly, it is possible to realize weight reduction and reduction of the material cost and the manufacturing cost while maintaining sufficient strength against an atmospheric pressure. In addition, in Japanese Patent Application Publication No. 2015-22806, a reinforcing structure including arch-shaped ribs for suppressing deformation of a ceiling plate of a vacuum chamber is provided at an outer side of the ceiling plate.

In a conventional plasma processing apparatus, an opening/closing mechanism for opening/closing the cover of the vacuum chamber is provided. In a large vacuum chamber corresponding to a large substrate having a side length of more than 2 meters, the strength is ensured by the reinforcing structures disclosed in Japanese Patent No. 5285403 and Japanese Patent Application Publication No. 2015-22806. However, the effect of weight reduction is not sufficient because the reinforcing structures have weights of about 1.5 tons and about 2.0 tons, respectively. Also, it is required to scale up the opening/closing mechanism. Recently, in view of cost reduction, the cover is opened/closed by a ceiling crane installed in a user's factory without using the opening/closing mechanism. However, in the case of the reinforcing structures disclosed in Japanese Patent No. 5285403 and Japanese Patent Application Publication No. 2015-22806, the weight of the cover exceeds a tolerable range of the ceiling crane due to the heavy weights of the reinforcing structures.

### SUMMARY OF THE INVENTION

In view of the above, the disclosure provides a reinforcing structure capable of realizing desired weight reduction, a vacuum chamber having the reinforcing structure, and a plasma processing apparatus.

In accordance with an aspect, there is provided a reinforcing structure in which a plurality of beam members provided on a top surface of a cover of a vacuum chamber for performing predetermined processing on a substrate is combined to reinforce the cover, including: a ring-shaped portion formed by arranging beam members in a ring shape at a central region of the top surface of the cover; and a radial portion formed by radially extending beam members from the ring-shaped portion.

### BRIEF DESCRIPTION OF THE DRAWINGS

The objects and features of the disclosure will become apparent from the following description of embodiments, given in conjunction with the accompanying drawings, in which:

FIG. 1 is a cross sectional view showing a plasma processing apparatus including a reinforcing structure according to an embodiment;

FIG. 2 is a perspective view showing an external appearance of a vacuum chamber of the plasma processing apparatus shown in FIG. 1;

FIG. 3 is a top view showing the reinforcing structure according to the embodiment;

FIG. 4 explains a state at the time of opening/closing a cover of the vacuum chamber by a crane;

FIG. 5 is a top view showing a reinforcing structure according to another embodiment; and

FIG. 6 is a top view showing a reinforcing structure according to still another embodiment.

### DETAILED DESCRIPTION OF THE EMBODIMENTS

Hereinafter, embodiments will be described with reference to the accompanying drawings.

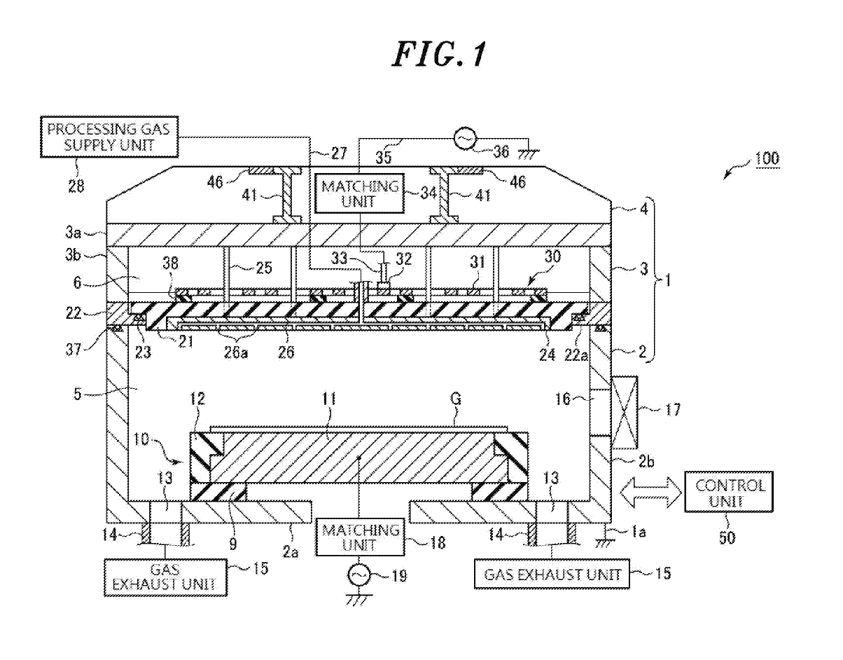

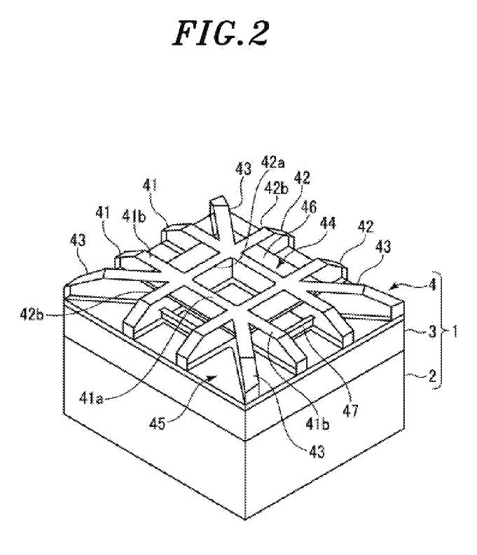

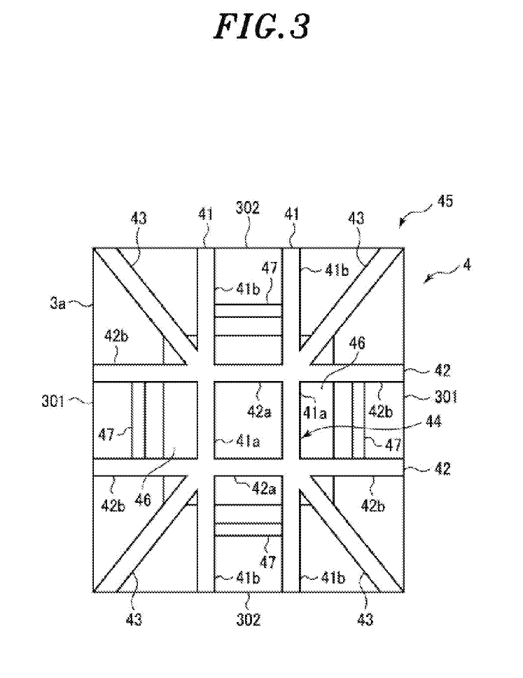

FIG. 1 is a cross sectional view showing a plasma processing apparatus including a reinforcing structure according to an embodiment. FIG. 2 is a perspective view showing an external appearance of a vacuum chamber of the plasma processing apparatus shown in FIG. 1. FIG. 3 is a top view showing the reinforcing structure according to the embodiment.

As shown in FIG. 1, a plasma processing apparatus 100 is configured as an inductively coupled plasma processing apparatus for performing plasma processing, e.g., plasma etching, on a rectangular glass substrate for use in FPD (hereinafter, simply referred to as “substrate”) G. The FPD may be a liquid crystal display (LCD), an electro Luminescence (EL) display, a plasma display panel (PDP) or the like.

The plasma processing apparatus 100 includes a vacuum chamber 1 having an inner wall surface made of a conductive material, e.g., anodically oxidized aluminum. The vacuum chamber 1 has a substantially rectangular parallelepiped shape and a rectangular cross sectional shape. The vacuum chamber 1 is grounded by a ground line 1a. The vacuum chamber 1 includes a chamber main body 2, a cover 3, and a reinforcing structure 4.

The chamber main body 2 has a bottom wall 2a and a sidewall 2b and an opening at an upper portion thereof. The opening can be opened/closed by the cover 3. By closing the opening by the cover 3, a processing space 5 is formed inside the chamber main body 2.

At a bottom portion in the processing space 5, a substrate mounting table 10 for mounting thereon the substrate G is provided on the bottom wall 2a of the chamber main body 2 through an insulating member 9 made of resin or insulating ceramic such as alumina or the like. The substrate mounting table 10 includes a base 11 made of a metal, e.g., aluminum, and an insulating ring 12 provided around the base 11. Although it is not illustrated, an electrostatic chuck for attracting and holding the substrate G is provided on a top surface of the substrate mounting table 10, and elevating pins used for transferring the substrate G penetrate through the substrate mounting table 10. Further, although it is not illustrated, the substrate mounting table 10 is provided with a temperature control unit for controlling a temperature of the substrate G and a temperature sensor.

A plurality of gas exhaust ports 13 is provided at the bottom wall 2a of the chamber main body 2. Gas exhaust lines 14 are connected to the respective gas exhaust ports 13. The gas exhaust lines 14 are connected to gas exhaust units 15, each including an automatic pressure control valve and a vacuum pump. The processing space 5 is vacuum-evacuated by the gas exhaust units 15 and a pressure in the processing space 5 is controlled to a predetermined pressure.

Provided at the sidewall 2b of the chamber main body 2 is a loading/unloading port 16 for loading/unloading the substrate G into/from the processing space 5. The loading/unloading port 16 can be opened/closed by a gate valve 17. A transfer chamber (not shown) is provided near the chamber main body 2. By opening the gate valve 17, the substrate G can be loaded into and unloaded from the processing space 5 through the loading/unloading port 16 by a transfer unit (not shown) provided in the transfer chamber. The base 11 of the substrate mounting table 10 is connected to a high frequency bias power supply 19 for applying a high frequency bias power for ion attraction via a matching unit 18.

The cover 3 includes a ceiling wall 3a, a sidewall 3b, and a dielectric wall 21 serving as a bottom wall. The dielectric wall 21 also serves as a ceiling wall of the chamber main body 2. A space surrounded by those walls becomes an antenna space 6. The dielectric wall 21 is made of quartz, ceramic such as Al₂O₃ or the like.

A ring-shaped supporting member 22 having an inwardly protruding ring-shaped supporting portion 22a is provided below the sidewall 3b. The dielectric wall 21 is supported by the ring-shaped supporting portion 22a. The dielectric wall 21 and the ring-shaped supporting member 22 are sealed by a seal ring 23.

A shower housing 24 for supplying a processing gas is made of a metal, e.g., aluminum. The shower housing 24 is fitted to a lower portion of the dielectric wall 21. The shower housing 24 is formed in a cross shape and has a structure, e.g., a beam structure, for supporting the dielectric wall 21 from the bottom. The dielectric wall 21 is divided into a plurality of pieces. The shower housing 24, as a beam, supports the divided pieces at contact portions between adjacent divided pieces. The shower housing 24 for supporting the dielectric wall 21 is suspended from the ceiling wall 3a by a plurality of suspenders 25. The ring-shaped supporting member 22 and the shower housing 24 may be coated with a dielectric material.

A gas channel 26 extending horizontally is formed in the shower housing 24. A plurality of gas injection holes 26a extending downward communicates with the gas channel 26. A gas supply line 27 is provided at a central portion of a top surface of the dielectric wall 21 to communicate with the gas channel 26. The gas supply line 27 penetrates through the ceiling wall 3a or the sidewall 3b and is connected to a processing gas supply unit 28 including a processing gas supply source, a valve system and the like. Therefore, when the plasma processing is performed, the processing gas is supplied from the processing gas supply unit 28 to the gas channel 26 in the shower housing 24 through the gas supply line 27 and then is injected into the processing space 5 through the gas injection holes 26a formed at the bottom surface of the shower housing 24.

A high frequency (RF) antenna 30 is provided in the antenna space 6. The RF antenna 30 is formed by arranging an antenna line 31 made of a highly conductive metal such as copper, aluminum or the like in a conventional shape such as a ring shape, a spiral shape or the like. The RF antenna 30 may be a multiplex antenna having a plurality of antenna sections.

A power feed member 33 extending to an upper portion in the antenna space 6 is connected to a terminal 32 of the antenna line 31. A matching unit 34 is connected to the power feed member 33. A high frequency power supply 36 is connected to the matching unit 34 through a power feed line 35. The antenna line 31 of the RF antenna 30 is separated from the dielectric wall 21 by a spacer 38 made of an insulating material.

By supplying a high frequency power having a predetermined frequency, e.g., 13.56 MHz, from the high frequency power supply 36 to the RF antenna 30, an induced electric field is generated in the processing space 5. The processing gas supplied from the shower housing 24 is converted into a plasma by the induced electric field. As a consequence, an inductively coupled plasma is generated.

When the cover 3 is attached to the chamber main body 2, the cover 3 is fixed by screws (not shown). A gap between the chamber main body 2 and the cover 3 is sealed by a seal ring 37.

As shown in FIGS. 2 and 3, the reinforcing structure 4 is formed by combining a plurality of beam members made of H-shaped steel and provided on a rectangular top surface of the ceiling wall 3a of the cover 3. Specifically, as shown in FIG. 3, the reinforcing structure 4 includes two first beam members 41 having a linear shape and disposed in parallel along the entire length of a pair of long sides 301 of the ceiling wall 3a of the cover 3 and two second beam members 42 having a linear shape and disposed in parallel along the entire length of a pair of short sides 302 of the ceiling wall 3a of the cover 3. The first beam members 41 and the second beam members 42 are arranged in a parallel cross shape. The reinforcing structure 4 further includes four third beam members 43 extending in a diagonal direction from intersection points between the first beam members 41 and the second beam members 41. These beam members are attached to the ceiling wall 3a by fastening units such as bolts or the like.

The first and the second beam members 41 and 42 are arranged such that the top surface of the ceiling wall 3a of the cover 3 is divided into (substantially) nine parts. Two central portions 41a of the two first beam members 41 and two central portions 42a of the two second beam members 42 form a ring-shaped portion 44 that is a rectangular frame body. End portions 41b disposed at both sides of the central portions 41a in the first beam members 41, end portions 42b disposed at both sides of the central portions 42a in the second beam members 42, and the third beam members 43 radially extend outward from the ring-shaped portion 44. These beam members form a radial portion 45. In other words, the reinforcing structure 4 includes the ring-shaped portion 44 formed by combining the beam members in a frame shape and provided at the central region of the top surface of the ceiling wall 3a of the cover 3, and the radial portion 45 formed by radially extending the beam members outward from the ring-shaped portion 44.

The end portions 41b of the first beam members 41 forming the radial portion 45 are perpendicular to the central portions 42a of the second beam members 42 forming the ring-shaped portion 44. The end portions 42b of the second beam members 42 forming the radial portion 45 are perpendicular to the central portions 41a of the first beam members 41 forming the ring-shaped portion 44. The third beam members 43 forming the radial portion extend in a diagonal direction from corners of the ring-shaped portion 44.

A plate-shaped member 46 is provided between adjacent ones of the beam members (the end portions 41b and 42b and the third beam members 43) forming the radial portion 45 to correct the adjacent beam members. The plate-shaped member 46 is provided to improve the reinforcing effect of the reinforcing structure 4. In the present embodiment, the plate-shaped member 46 is provided at the entire gap between the adjacent beam members of the radial portion 45. However, the plate-shaped member 46 is not necessarily provided at the entire gap between the adjacent beam members and may be provided at at least a part of the gap. In the case of providing the plate-shaped member 46 at a part of the entire gap, it is ideal that the plate-shaped member 46 is provided symmetrically. However, when the cover 3 has strength variation in terms of structure, the plate-shaped members 46 may be provided at a mechanically weak portion without symmetry. A width of the plate-shaped member 46 is set while considering balance between the reinforcing effect and the weight increase. The width of the plate-shaped member 46 is preferably about 20% to 80% and more preferably about 40% to 60% of the length of the beam members of the radial portion 45 which are adjacent thereto.

An auxiliary beam member 47 is provided between the two facing end portions 41b of the two first beam members 41 and between the two facing end portions 42b of the two second beam members 42 at the outer side of the plate-shaped member 46.

With the combination of the ring-shaped portion 44 and the radial portion 45, the reinforcing structure 4 can maintain the high reinforcing effect while realizing the weight reduction.

As described above, the ring-shaped portion 44 is provided at the central region of the top surface of the ceiling wall 3a. A length of each side of the ring-shaped portion 44 is preferably about 30% to 80% of the side length of the ceiling wall 3a. Accordingly, the reinforcing effect of the cover 3 can be maintained at a high level. The ring-shaped portion 44 has therein a space and the matching unit 34 that is a large device can be inserted in the space. As a consequence, it is possible to realize space saving. A large device that can be located in the ring-shaped portion 44 is not limited to the matching unit 34.

The plasma processing apparatus 100 further includes a control unit 50 having a microprocessor (computer) for controlling the respective components of the plasma processing apparatus 10.

In the plasma processing apparatus 100 configured as described above, first, the processing space 5 is exhausted by the gas exhaust unit 15 so that a pressure in the processing space 5 can be set to a predetermined level. Next, the gate valve 17 is opened and the substrate G is loaded through the loading/unloading port 16 by a transfer unit (not shown). Then, the substrate G is mounted on the substrate mounting table 10. After the transfer unit is retreated from the processing space 5, the gate valve 17 is closed.

In that state, the processing space 5 is vacuum-evacuated and a pressure in the processing space 5 is controlled to a predetermined vacuum level by a pressure control valve (not shown). At the same time, a predetermined processing gas is supplied into the processing space 5 from the processing gas supply unit 28 through the gas supply line 27 and the shower housing 24.

Next, a high frequency power having a predetermined frequency (e.g., 13.56 MHz) is applied at a predetermined power level from the high frequency power supply 36 to the RF antenna 30. Accordingly, an induced electric field is uniformly generated in the processing space 5 through the dielectric wall 21. The processing gas is converted into a plasma in the processing space 5 by the induced electric field thus generated, thereby generating a high-density inductively coupled plasma. The predetermined plasma processing, e.g., film formation or etching, is performed on the substrate G by the plasma thus generated.

When the substrate G is a large substrate having a side length of more than 2 meters, the vacuum chamber 1 is also scaled up. Therefore, the reinforcing structure 4 is provided to reduce the weight of the cover 3 while maintaining a sufficient strength against an atmospheric pressure at the time of setting the processing space 5 to a vacuum state.

The techniques for reinforcing the cover by the reinforcing structure are disclosed in Japanese Patent No. 5285403 and Japanese Patent Application Publication No. 2015-22806. In the case of considering application to a large apparatus, ensuring strength is important in the technique disclosed in Japanese Patent Application Publication No. 2015-22806 and, thus, the weight of the reinforcing structure is extremely increased to about 2 tons. The reinforcing structure disclosed in Japanese Patent No. 5285403 which is intended to ensure the strength and reduce the weight also has a weight of about 1.5 tons, which is insufficient to realize the weight reduction.

On the other hand, the reinforcing structure 4 of the present embodiment is formed by combining a plurality of beam members on the rectangular top surface of the ceiling wall 3a of the cover 3. Further, the reinforcing structure 4 of the present embodiment includes the ring-shaped portion 44 formed by combining the beam members in a frame shape and provided at the central region of the top surface of the ceiling wall 3a and the radial portion 45 formed by radially extending the beam members outward from the ring-shaped portion 44. At this time, a certain level of strength can be ensured by the ring-shaped portion 44 provided at the central region and a sufficient strength can be obtained by radially arranging the beam members from the ring-shaped portion 44.

The structure obtained by combining the ring-shaped portion 44 provided at the central region and the radial portion 45 provides a high reinforcing effect. In the case of employing such a structure, even if the thicknesses of the beam members are thinner than conventional ones, a desired strength can be ensured. In addition, the number of the beam members can be reduced due to a simple structure. Accordingly, the weight of the reinforcing structure 4 can be reduced. At this time, a length of each side of the ring-shaped portion 44 is preferably about 30% to 60% of the side length of the ceiling wall 3a in order to maintain the reinforcing effect of the cover 3 at a high level.

By providing the ring-shaped portion 44 at the central region, a space can be ensured at the central region on the top surface of the cover 3 and a large device such as the matching unit 34 or the like can be installed therein. As a result, the space saving can be realized.

The end portions 41b of the first beam members 41 which form the radial portion 45 are perpendicular to the central portions 42a of the second beam members 42 forming the ring-shaped portion 44. The end portions 42b of the second beam members 42 which form the radial portion 45 are perpendicular to the central portions 41a of the first beam members 41 forming the ring-shaped portion 44. Therefore, the reinforcing effect of the radial portion 45 can be improved. By providing, as the radial portion 45, the four third beam members 43 extending in a diagonal direction from the intersection points between the first beam members 41 and the second beam members 42, the inner portion of the ring-shaped portion 44 of the cover 3 is reinforced and, thus, the reinforcing effect can be further increased. With the above configuration, the weight reduction effect can be further improved.

Further, the reinforcing structure 4 includes the two first beam members 41 having a linear shape and disposed in parallel along the entire length of a pair of long sides 301 of the ceiling wall 3a of the cover 3 and the two second beam members 42 having a linear shape and disposed in parallel along the entire length of a pair of short sides 302 of the ceiling wall 3a of the cover 3. These beam members are arranged in a parallel cross shape, thereby forming the ring-shaped portion 44 and the radial portion 45. This is basically the combination of the long beam members. The combination of the long beam members provides a higher reinforcing effect compared to the combination of short beam members. Therefore, the reinforcing effect can be further improved and the weight reduction effect can be further improved. Further, by arranging the two first beam members 41 and the two second beam members 42 such that the top surface of the ceiling wall 3a of the cover 3 is divided into substantially nine parts, the reinforcing effect and the weight reduction effect can be further improved.

Furthermore, by providing the plate-shaped member 46 at the gap between adjacent ones of the beam members forming the radial portion 45, the reinforcing effect to the reinforcing structure 4 can be improved. Since the plate-shaped member 46 has a plate shape, the reinforcing effect can be improved without a considerable increase in the weight, which is advantageous when it is required to further improve the reinforcing effect obtained by combining the ring-shaped portion 44 and the radial portion 45. At this time, the width of the plate-shaped member 46 may be appropriately set while considering the balance between the reinforcing effect and the weight increase. In other words, when the width of the plate-shaped member 46 is increased, the reinforcing effect is improved. However, the reinforcing effect is saturated and an adverse effect due to the increase in the weight of the plate-shaped member 46 is increased when the width exceeds a certain level. From the above, the width of the plate-shaped member 46 is preferably about 20% to 80% and more preferably about 40% to 60% of the length of the beam members adjacent to the plate-shaped member 46. The plate-shaped member 46 is not necessarily provided at the entire gap between the adjacent beam members. A certain effect can be obtained by providing the plate-shaped member 46 at at least a part of the gap between the adjacent beam members.

In the present embodiment, the reinforcing structure 4 capable of realizing desired weight reduction can be obtained. In the case of applying the reinforcing structure 4 of the present embodiment to a large plasma processing apparatus corresponding to a large substrate, it is possible to reduce the weight of the reinforcing structure which is about 1.5 tons in Japanese Patent No. 5285403 and about 2 tons in Japanese Patent Application Publication No. 2015-22806 to about 1 ton.

Therefore, in the case where the plasma processing apparatus 100 has the opening/closing mechanism of the cover 3, the scaling up of the opening/closing mechanism can be suppressed and a cost increase of the opening/closing mechanism can be prevented.

Since the weight of the reinforcing structure 4 can be reduced, the weight of the cover 3 can be within a tolerable range of a conventional ceiling crane. Accordingly, the cover can be opened/closed by the ceiling crane installed in a user's factory without using the opening/closing mechanism. As a result, the apparatus cost can be reduced.

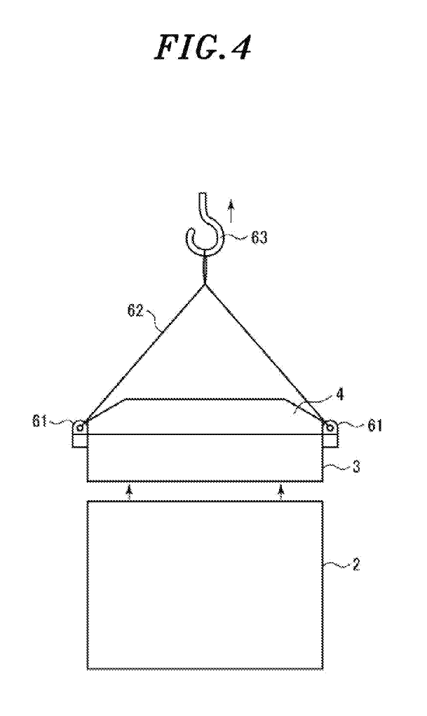

In the case of opening/closing the cover 3 by the crane, a crane opening/closing operation is performed by providing a crane opening/closing jig 61 at the cover 3 and directly or indirectly engaging a hook 63 of the crane with the crane opening/closing jig 61, as can be seen from FIG. 4. In this example, the crane opening/closing jigs 61 are provided at a plurality of positions of the cover and a rope is coupled to the crane opening/closing jigs 61. The rope 62 is engaged with the hook 63 of the crane and the cover 3 is moved up and down by the crane. Accordingly, the opening/closing of the cover 3 is carried out. It is also possible to provide a crane opening/closing jig directly coupled to the hook of the crane at the cover 3.

The present disclosure is not limited to the above embodiments and may be variously modified within the scope of the present disclosure. For example, in the above embodiments, the present disclosure is applied to the inductively coupled plasma processing apparatus in which the dielectric wall is used as the ceiling wall of the chamber main body defining the processing space. However, the present disclosure may be applied to an inductively coupled plasma processing apparatus using a metal wall instead of the dielectric wall and may also be applied to another plasma processing apparatus such as a capacitively coupled parallel plate plasma processing apparatus, a microwave plasma processing apparatus or the like. Further, the present disclosure is not limited to the plasma processing apparatus and may be applied to a vacuum chamber for performing vacuum processing using no plasma, such as thermal CVD or the like.

The above embodiments have described the example in which the third beam members 43 extend diagonally. In that case, it is assumed that the ceiling wall 3a and the ring-shaped portion 44 have similar shapes having the same aspect ratio. However, the ceiling wall 3a and the ring-shaped portion 44 do not necessarily have the similar shapes. In that case, the third beam members 43 may be arranged to connect the corners of the ring-shaped portion 44 and the corners of the ceiling wall 3a.

The above embodiments have described the example in which the reinforcing structure includes the ring-shaped portion 44 and the radial portion 45 which are formed by arranging in a parallel cross shape the two first beam members 41 having a linear shape and disposed in parallel to the pair of long sides 301 of the ceiling wall 3a of the cover 3 and the two second beam members 42 having a linear shape and disposed in parallel to the pair of short sides 302 of the ceiling wall 3a of the cover 3. However, the present disclosure is not limited thereto.

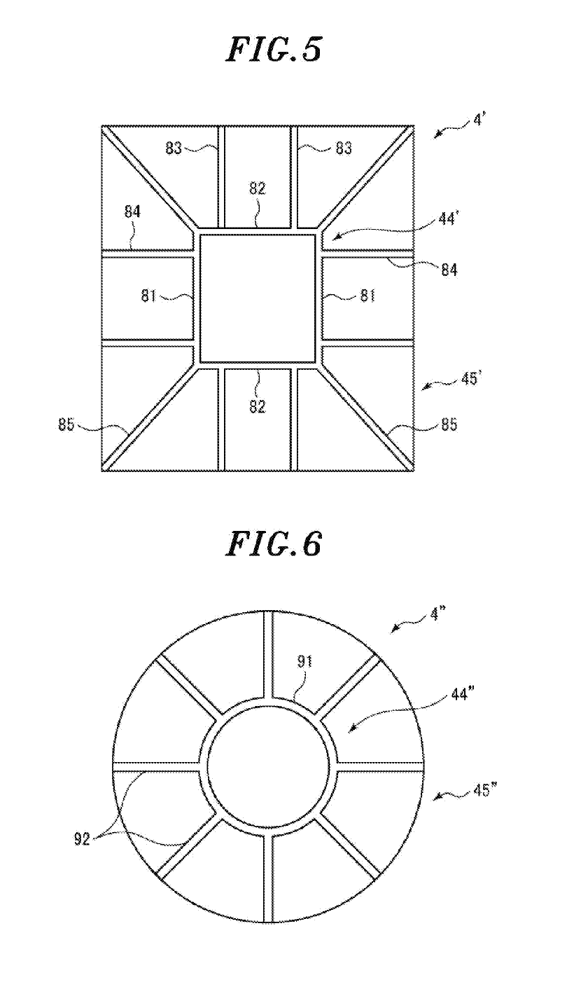

For example, as shown in FIG. 5, there may be provided a reinforcing structure 4′ including a ring-shaped portion 44′ formed by combining first beam members 81 corresponding to long sides and second beam members 82 corresponding to short sides and a radial portion 45′ formed by third beam members 83 perpendicularly extending outward from the second beam members 82 forming the ring-shaped portion 44′, fourth beam members 84 perpendicularly extending outward from the first beam members 81, and fifth beam members 85 obliquely extending outward from corners of the ring-shaped portion 44′.

The above embodiments have described the example in which the present disclosure is applied to the vacuum chamber having a rectangular cross sectional shape and configured to process a rectangular substrate. However, it is not limited thereto and the present disclosure may also be applied to a vacuum chamber having a circular cross sectional shape and configured to process a circular substrate. In that case, there is provided a reinforcing structure 4″ including a cylindrical ring-shaped portion 44″ formed by a circular beam member 91 provided at a central region of a top surface of a circular cover and a radial portion 45″ formed by arranging a plurality of linear beam members 92 directed outward from the cylindrical ring-shaped portion 44″, as can be seen from FIG. 6.

The above embodiments have described the case of using H-shaped steel for the beam members forming the reinforcing structure. However, steel having other shapes such as an L-shaped cross section (angle), a C-shaped cross section (channel) and the like may be used instead of H-shaped steel. Further, other types of materials such as a timber, a hollow pipe, a plate and the like may also be used.

While the disclosure has been shown and described with respect to the embodiments, it will be understood by those skilled in the art that various changes and modifications may be made without departing from the scope of the disclosure as defined in the following claims.

What is claimed is:

1. A reinforcing structure in which a plurality of beam members provided on a top surface of a cover of a vacuum chamber for performing predetermined processing on a substrate is combined to reinforce the cover, the reinforcing structure comprising:
a ring-shaped portion formed by arranging beam members in a ring shape at a central region of the top surface of the cover; and
a radial portion formed by radially extending beam members from the ring-shaped portion.

2. The reinforcing structure of claim 1, wherein the vacuum chamber has a rectangular parallelepiped shape,
the top surface of the cover has a rectangular shape, and
the ring-shaped portion is a rectangular frame body.

3. The reinforcing structure of claim 2, wherein the radial portion includes beam members extending in a direction perpendicular to sides of the ring-shaped portion and beam members extending from corners of the ring-shaped portion toward corners of the top surface of the cover.

4. The reinforcing structure of claim 3, wherein the beam members extending from the corners of the ring-shaped portion toward the corners of the top surface of the cover extend diagonally.

5. The reinforcing structure of claim 2, wherein the rectangular top surface of the cover has a pair of first sides and a pair of second sides,
wherein the reinforcing structure includes two first beam members disposed in parallel to the pair of first sides of the rectangular top surface of the cover and two second beam members disposed in parallel to the pair of second sides of the rectangular top surface of the cover,
wherein the first beam members and the second beam members are arranged in a parallel cross shape,
wherein central portions of the first beam members and central portions of the second beam members form the ring-shaped portion, and
wherein end portions disposed at both sides of the central portions of the first beam members and end portions disposed at both sides of the central portions of the second beam members form a part of the beam members of the radial portion.

6. The reinforcing structure of claim 5, wherein the radial portion further includes beam members extending from corners of the ring-shaped portion toward corners of the top surface of the cover.

7. The reinforcing structure of claim 6, wherein the beam members extending from the corners of the ring-shaped portion toward the corners of the top surface of the cover extend diagonally.

8. The reinforcing structure of claim 5, wherein the first beam members and the second beam members are provided such that the top surface of the cover is divided into nine parts.

9. The reinforcing structure of claim 1, wherein a plate-shaped member is provided at at least a part of a gap between adjacent ones of the beam members forming the radial portion to connect the adjacent beam members.

10. A vacuum chamber for performing predetermined processing on a substrate, comprising:
a chamber main body for defining a processing space, the chamber main body having an opening at an upper portion thereof;
a cover configured to open and close the opening of the chamber main body; and
the reinforcing structure, disclosed in claim 1, formed by combining the plurality of beam members provided at the top surface of the cover.

11. The vacuum chamber of claim 10, wherein the cover further includes a crane opening/closing jig that is directly or indirectly engaged with a hook of a crane at the time of opening and closing the cover by the crane.

12. A plasma processing apparatus for performing plasma processing on a substrate, comprising:
a vacuum chamber;
a gas exhaust unit configured to vacuum-evacuate a processing space defined in the vacuum chamber;
a gas supply unit configured to supply a processing gas into the processing space; and
a plasma generation unit configured to generate a plasma in the processing space,
wherein the vacuum chamber includes:
a chamber main body for defining the processing space, the chamber main body having an opening at an upper portion thereof;
a cover configured to open and close the opening of the chamber main body; and
the reinforcing structure, disclosed in claim 1, formed by combining the plurality of beam members provided at the top surface of the cover.

13. The plasma processing apparatus of claim 12, wherein the cover further includes a crane opening/closing jig that is directly or indirectly engaged with a hook of a crane at the time of opening and closing the cover by the crane.
